(19) United States
(12) Patent Application Publication
(10) Pub. No.: US 2025/0294945 A1
(43) Pub. Date: Sep. 18, 2025

(54) LIGHT-EMITTING COMPONENT AND LIGHT-EMITTING ELEMENT

(71) Applicant: Xiamen San'an Optoelectronics Co., Ltd., Fujian (CN)

(72) Inventors: Xueping YE, Fujian (CN); Te-ling HSIA, Fujian (CN); Chia-en LEE, Fujian (CN)

(73) Assignee: Xiamen San'an Optoelectronics Co., Ltd., Fujian (CN)

(21) Appl. No.: 19/221,431

(22) Filed: May 28, 2025

Related U.S. Application Data
(63) Continuation of application No. PCT/CN2023/134465, filed on Nov. 27, 2023.

(30) Foreign Application Priority Data
Nov. 29, 2022 (CN) 202211512417.7

(51) Int. Cl. H10H 29/49

(52) U.S. Cl. CPC H10H 29/49

(57) ABSTRACT

A light-emitting component includes a circuit board and groups of light-emitting elements arranged at intervals on the circuit board. The light-emitting element includes at least two adjacent light-emitting units and a conductive bridge that electrically connecting the light-emitting units in series. The light-emitting unit includes an epitaxial structure and at least one metal electrode. The epitaxial structure has opposite first and second surfaces. The conductive bridge is bridged across a side of the second surface. When viewing the epitaxial structure from above the light-emitting element, the first surface has a side edge close to the conductive bridge, and an orthogonal projection of the side edge on the circuit substrate falls within an orthogonal projection of the second surface on the circuit board. The at least one metal electrode is disposed between the epitaxial structure and the circuit board, and is electrically connected to the epitaxial structure and the circuit board.

### CROSS-REFERENCE TO RELATED APPLICATION

This application is a continuation of international application of PCT application serial no. PCT/CN2023/134465, filed on Nov. 27, 2023, which claims the priority benefit of China application no. 202211512417.7, filed on Nov. 29, 2022. The entirety of each of the above-mentioned patent applications are hereby incorporated by reference herein and made a part of this specification.

### TECHNICAL FIELD

This disclosure relates to a field of semiconductor manufacturing technology, and in particular to a light-emitting component, a light-emitting element, and a manufacturing method.

### DESCRIPTION OF RELATED ART

Micro LED display technology refers to a display technology using self-luminous micro-scale LEDs as light-emitting pixel units, assembling the self-luminous micro-scale LEDs onto a driving panel to form a high-density LED array. Due to the small size, high integration, and self-luminous characteristics of Micro LED chips, the display aspects thereof have greater advantages in brightness, resolution, contrast, energy consumption, service life, response speed, and thermal stability compared to LCD and OLED.

To meet the demand for LED brightness, high-voltage Micro LED chips have emerged. Through microfabrication technology, mutual isolation between adjacent LED units is achieved on the epitaxial layer, and then the LED unit arrays are connected in series by depositing metal, so that the LED products have better photoelectric properties, and meet the market demand for high optical power density. However, in the manufacturing process of existing high-voltage Micro-LED chips, there is a problem of poor production yield leading to insufficient performance of the chip.

### SUMMARY

This invention provides a light-emitting component. The light-emitting component at least includes a circuit board, a plurality of groups of light-emitting elements and a conductive bridge.

The light-emitting element includes at least two adjacent light-emitting units. The plurality of groups of light-emitting elements are arranged at intervals on the circuit board. The conductive bridge is bridged on the adjacent light-emitting units to electrically connect the adjacent light-emitting units in series. The light-emitting unit includes an epitaxial structure and at least one metal electrode. The epitaxial structure has a first surface and a second surface opposite to each other. The first surface is a light exit surface. The conductive bridge is bridged across a side of the second surface. Viewing the epitaxial structure from above the light-emitting element, the first surface has a side edge close to the conductive bridge, and an orthogonal projection of the side edge on the circuit board falls within an orthogonal projection of the second surface on the circuit board. The metal electrode is disposed between the epitaxial structure and the circuit board, and is electrically connected to the epitaxial structure and circuit board respectively.

Through the aforementioned structure arrangement, a bridging distance of the conductive bridge may be effectively reduced, thereby reducing the overall size of the chip. Additionally, etching damage may be reduced while a high-voltage characteristic of the device is achieved, thereby enhancing the light-emitting efficiency.

In an embodiment, the epitaxial structure further has sidewalls connected to the first surface and the second surface, the sidewalls extending from the side edge to the second surface are defined as groove sidewalls, the groove sidewall is formed by at least one plane or at least one arc surface or a combination thereof, so that a groove is formed between the groove sidewalls of the light-emitting units connected in series with each other.

In an embodiment, the groove sidewall is an inclined plane or an inclined arc surface.

In an embodiment, when the groove sidewall is an inclined arc surface, an angle β between a tangent of the inclined arc surface and the second surface is greater than or equal to 30° and less than 90°, and the angle β gradually increases or gradually decreases.

In an embodiment, the groove sidewall is formed by at least two planes with different inclined angles or at least two arc surfaces with different radii of curvature or a combination thereof.

In an embodiment, the groove sidewall includes a first inclined surface, a horizontal surface, and a second inclined surface extending sequentially from a direction of the first surface toward the second surface. An inclined angle of the first inclined surface is less than or equal to an inclined angle of the second inclined surface. Through the aforementioned limitation on the groove sidewall, the groove has a structure that is wider on the top and narrower on the bottom, which helps reduce the bridging distance of the conductive bridge. The stability of the bridge is ensured, making the conductive bridge less prone to defects such as cracks or fractures, and improving the reliability of the device.

In an embodiment, the groove has a bottom edge located on a connection between the groove sidewall and the second surface. An angle θ between a common perpendicular of the side edge and the bottom edge and the second surface is less than 90°.

In an embodiment, a range of the angle θ is greater than or equal to 45° and less than 70°, or greater than or equal to 70° and less than 80°, or greater than or equal to 80° and less than 90°. The aforementioned limitation on the angle θ may effectively avoid the angle θ being too small which would affect the light-emitting area, or too large which would affect the manufacturing process.

In an embodiment, a range of the angle θ is greater than 45° and less than 75°, which is beneficial for covering the insulation layer to protect the epitaxial structure.

In an embodiment, an opening of the groove gradually decreases from the direction of the first surface toward the second surface.

In some embodiments, there is a minimum horizontal distance between the groove sidewalls of the light-emitting units connected in series. The minimum horizontal distance is greater than or equal to 2 microns and less than or equal to 5 microns. Adopting the distance range is beneficial for the light-emitting effect of the light-emitting element as well as ensuring the stability of the manufacturing process.

In an embodiment, there is a maximum horizontal distance between the light-emitting units connected in series. The maximum horizontal distance is less than a minimum spacing between the adjacent light-emitting elements.

In an embodiment, in the light-emitting element composed of two light-emitting units connected in series, a length of the light-emitting element does not exceed 200 microns, and a width of the light-emitting element does not exceed 100 microns. Through the aforementioned limitation on the size of the light-emitting element, the light-emitting component being too large is avoided, and the cost is reduced.

In an embodiment, a thickness range of the conductive bridge is 0.5 microns to 1.5 microns. Through the thickness limitation of the conductive bridge 3, an effective series connection of the light-emitting units by the conductive bridge 3 is ensured. A material of the conductive bridge includes at least one of a dielectric medium material, a metal material, and a semiconductor material. In this embodiment, the metal material is preferred.

In an embodiment, the light-emitting element further includes a medium layer and an insulation layer. The medium layer covers the second surface of the light-emitting unit and extends across the groove to cover the second surface of another light-emitting unit connected in series with the light-emitting unit. The insulation layer covers the medium layer and the conductive bridge, or covers the medium layer and extends to cover a portion of the sidewall and the conductive bridge.

In an embodiment, a thickness range of the medium layer is 0.5 microns to 1.5 microns. The medium layer at least includes a reflection layer. The thickness limitation of the medium layer avoids the medium layer being too thin to provide support, or too thick which wastes materials and increases a process of etching.

In an embodiment, the epitaxial structure includes a first type semiconductor layer, a light-emitting layer, and a second type semiconductor layer stacked sequentially from the first surface to the second surface. At least one through hole exposing the first type semiconductor layer or the second type semiconductor layer is disposed on the medium layer and the insulation layer. The conductive bridge covers the medium layer, and is electrically connected to the first type semiconductor layer and the second type semiconductor layer of the light-emitting units connected in series with each other respectively through the through hole. The aforementioned design of the medium layer not only enhances the structural support of the entire light-emitting element, but also increases a contact area between the conductive bridge and the light-emitting element, which prevents defects such as breakage or cracks in the manufacturing process, so that the conductive bridge becomes thinner. At the same time, problems such as height differences or film coating discontinuities in the conductive bridge may be effectively avoided. Only film deposition on the equal height medium layer is needed, which is beneficial for the stability of the device in the process.

In an embodiment, a range of distance H from the electrode of the conductive bridge electrically connected to the first type semiconductor layer of the light-emitting units connected in series to the bottom of the groove is set to 0.5 microns to 3 microns, to shorten the bridging distance of the conductive bridge while avoiding the distance being too small which would affect the conductive performance of the series connection.

This disclosure provides a light-emitting element. The light-emitting element includes at least two adjacent light-emitting units and a conductive bridge. The conductive bridge bridges on the adjacent light-emitting units to electrically connect the adjacent light-emitting units in series. The light-emitting unit includes an epitaxial structure and at least one metal electrode. The epitaxial structure has a first surface and a second surface opposite to each other. The first surface is a light exit surface. The conductive bridge is bridged across a side of the second surface. Viewing the epitaxial structure from above the light-emitting element, the first surface has a side edge close to the conductive bridge, and an orthogonal projection of the side edge on the epitaxial structure falls within an orthogonal projection of the second surface on the epitaxial structure.

Through the aforementioned structure arrangement, the bridging distance of the conductive bridge may be effectively reduced, thereby reducing the overall size of the chip. Additionally, etching damage may be reduced while a high voltage characteristic of the device is achieved, thus enhancing the light-emitting efficiency.

In an embodiment, the epitaxial structure further has sidewalls connected to the first surface and the second surface, the sidewalls extending from the side edge to the second surface are defined as groove sidewalls, and the groove sidewall is formed by at least one plane or at least one arc surface or a combination thereof, so that a groove is formed between the groove sidewalls of the light-emitting units connected in series with each other.

In an embodiment, the light-emitting element further includes a medium layer and an insulation layer. The medium layer covers the second surface of the light-emitting unit and extends across the groove to cover the second surface of another light-emitting unit connected in series with the light-emitting unit. The insulation layer covers the medium layer and the conductive bridge, or covers the medium layer and extends to cover a portion of the sidewall and the conductive bridge.

This disclosure also provides a manufacturing method of a light-emitting component, including the following steps. An epitaxial structure is formed on a growth substrate, wherein the epitaxial structure has a first surface and a second surface opposite to each other, and includes a first type semiconductor layer, a light-emitting layer, and a second type semiconductor layer stacked sequentially from the first surface to the second surface. A medium layer is formed on the second surface of the epitaxial structure. A conductive bridge is formed on the medium layer. Next, an insulation layer is deposited, and the insulation layer covers the medium layer and the conductive bridge as well as a portion of the sidewall of the epitaxial structure. Several metal electrodes are formed on the insulation layer by an evaporation process. Conductive pads are formed and transferred to a temporary substrate. Next, the growth substrate is removed to expose the first surface of the epitaxial structure. A portion of the epitaxial structure is removed from the first surface toward the second surface to form a groove, the groove divides the epitaxial structure into a series of light-emitting units, and an opening of the groove gradually decreases from the direction of the first surface toward the second surface.

Other features and beneficial effects of the disclosure are elaborated in the subsequent specification, and partially become apparent from the specification, or understood through the implementation of the disclosure.

### BRIEF DESCRIPTION OF THE DRAWINGS

In order to more clearly describe the technical solutions in the embodiments of the disclosure or in the prior art, a simple introduction is given below to the drawings needed in the description of the embodiments or the prior art. Obviously, the drawings described below are some embodiments of the disclosure. For persons skilled in the art, other drawings may be obtained based on these drawings without creation.

FIG. 1 is a cross-sectional view of a light-emitting component provided by an embodiment of the disclosure.

FIG. 2 is a top view of a light-emitting component provided by the disclosure.

FIG. 3 to FIG. 7 are cross-sectional views of light-emitting components of other embodiments provided by the disclosure.

FIG. 8 to FIG. 12 are views of processes of a manufacturing method of a light-emitting component.

### DESCRIPTION OF THE EMBODIMENTS

To make the purpose, technical solutions, and advantages of the embodiments of the disclosure clearer, the technical solutions in the embodiments of the disclosure are described clearly and completely in conjunction with the drawings in the embodiments of the disclosure. The technical features designed in the different embodiments of the disclosure described below may be combined with each other without constituting conflicts with each other.

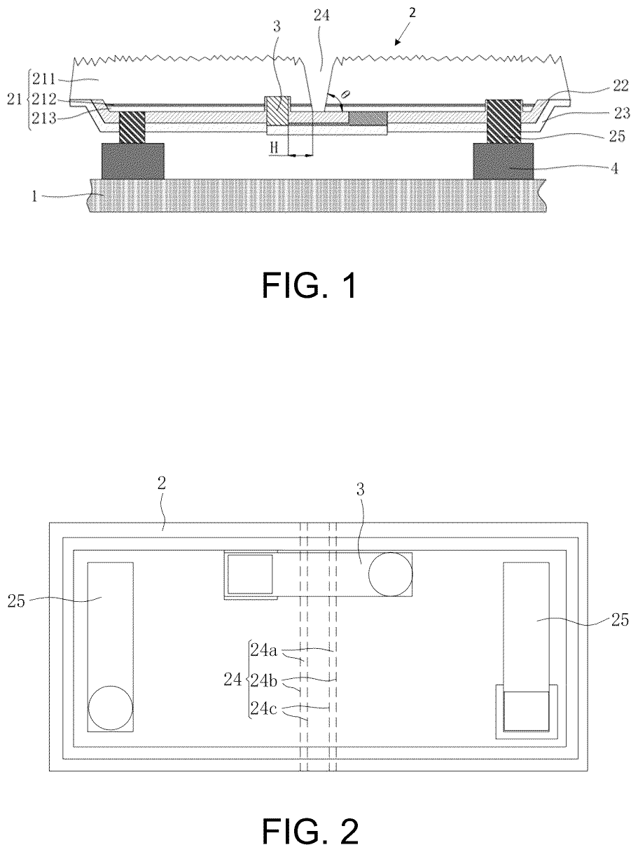

Referring to FIG. 1, FIG. 1 is a cross-sectional view of a light-emitting component provided by an embodiment of the disclosure. To achieve at least one of the aforementioned advantages or other advantages, an embodiment of the disclosure provides a light-emitting component. The light-emitting component may at least include a circuit board 1, a plurality of groups of light-emitting elements 2, and a conductive bridge 3.

The plurality of groups of light-emitting elements 2 are arranged at intervals on the circuit board 1. The circuit board 1 may be a complementary metal-oxide-semiconductor (CMOS) substrate, a liquid crystal on silicon (LCOS) substrate, a thin film transistor (TFT) substrate, or other substrates with working circuits, to drive the plurality of groups of light-emitting elements 2 to emit light of corresponding colors, which is not limited thereto.

Each light-emitting element 2 includes at least two adjacent light-emitting units. The conductive bridge 3 is bridged on the adjacent light-emitting units to form an electrical connection. In this embodiment, preferably, the light-emitting element 2 includes two light-emitting units. It should be noted that the light-emitting element 2 is not limited to the two light-emitting units shown in FIG. 1, and persons skilled in the art may dispose the quantity according to actual requirements. In addition, the connection relationship between each light-emitting unit is not limited to series connection, and may also be set to parallel connection or series-parallel hybrid connection according to actual requirements. In this embodiment, preferably, the light-emitting element 2 includes two adjacent light-emitting units, and the adjacent light-emitting units are connected in series with each other. Preferably, in the light-emitting element 2 composed of the two light-emitting units connected in series with each other, the light-emitting element 2 is generally rectangular or quasi-rectangular, a length of the light-emitting element 2 does not exceed 200 microns, and a width of the light-emitting element 2 does not exceed 100 microns. Through the aforementioned limitation on the dimension of the light-emitting element 2, the light-emitting component being too large may be avoided, the light efficiency is ensured, and the production cost is reduced.

A thickness range of the conductive bridge 3 is 0.5 microns to 1.5 microns. Through the thickness limitation of the conductive bridge 3, an effective series connection of the light-emitting units by the conductive bridge 3 is ensured. A material of the conductive bridge 3 includes at least one of a dielectric medium material, a metal material, and a semiconductor material. In this embodiment, the metal material is preferred.

Each light-emitting unit includes at least an epitaxial structure 21 and at least one metal electrode 25. The epitaxial structure 21 has a first surface and a second surface opposite to each other. The first surface is a light exit surface. The conductive bridge 3 is bridged on a side of the second surface, that is, the conductive bridge 3 is disposed between the light-emitting element 2 and the circuit board 1. The epitaxial structure 21 includes a first type semiconductor layer 211, a light-emitting layer 212, and a second type semiconductor layer 213 stacked sequentially from a direction of the first surface toward the second surface.

The first type semiconductor layer 211 may be composed of III-V group or II-VI group semiconductor compounds, and may be doped with a first dopant. The first type semiconductor layer 211 may be composed of a semiconductor material having a chemical formula In_{X1}Al_{Y1}Ga_{1-X1-Y1}N (0≤X1≤1,0≤Y1≤1, 0≤(X1+Y1)≤1), such as GaN, AlGaN, InGaN, and InAlGaN, or a material selected from AlGaAs, GaP, GaAs, GaAsP, and AlGalnP. In addition, the first dopant may be an n-type dopant, such as Si, Ge, Sn, Se, and Te. When the first dopant is the n-type dopant, the first type semiconductor layer 211 doped with the first dopant is an n-type semiconductor layer. The first dopant may also be a p-type dopant, such as Mg, Zn, Ca, Sr, and Ba, in which case the first type semiconductor layer 211 doped with the first dopant is a p-type semiconductor layer. The first surface of the first type semiconductor layer 211 is the light exit surface. In order to improve the light efficiency of the light-emitting element 2, the first surface of the first type semiconductor layer 211 may be roughened to form a roughened structure. In some optional embodiments, the first surface may also not undergo roughening treatment.

The light-emitting layer 212 is disposed between the first type semiconductor layer 211 and the second type semiconductor layer 213. The light-emitting layer 212 is a region that provides light radiation for a recombination of electrons and holes. Different materials may be selected according to different emission wavelengths. Adjusting a composition ratio of the semiconductor material in the light-emitting layer 212 expects to radiate light of different wavelengths. The light-emitting layer 212 may be a single quantum well or a periodic structure of a plurality of quantum wells. The light-emitting layer 212 includes a well layer and a barrier layer, where the barrier layer has a larger bandgap than the well layer. The light efficiency of the light-emitting layer 212 may be improved by changing the material of the quantum wells, a number of paired quantum wells and quantum barriers, thickness and/or other features in the light-emitting layer 212.

The second type semiconductor layer 213 is formed on the light-emitting layer 212, and may be composed of III-V group or II-VI group semiconductor compounds. The second type semiconductor layer 213 may be doped with a second dopant. The second type semiconductor layer 213 may be composed of a semiconductor material having a chemical formula In_{X2}Al_{Y2}Ga_{1-X2-Y2}N (0≤X2≤1, 0≤Y2≤1, 0≤(X2+Y2)≤1) or a material selected from AlGaAs, GaP, GaAs, GaAsP, and AlGalnP. When the second dopant is a p-type dopant, such as Mg, Zn, Ca, Sr, and Ba, the second type semiconductor layer 213 doped with the second dopant is a p-type semiconductor layer. The second dopant may also be an n-type dopant, such as Si, Ge, Sn, Se, and Te. When the second dopant is an n-type dopant, the second type semiconductor layer 213 doped with the second dopant is an n-type semiconductor layer. When the first type semiconductor layer 211 is an n-type semiconductor layer, the second type semiconductor layer 213 is a p-type semiconductor layer. Conversely, when the first type semiconductor layer 211 is a p-type semiconductor layer, the second type semiconductor layer 213 is an n-type semiconductor layer.

The epitaxial structure 21 may further include other layer materials, such as a current spreading layer, a window layer, or an ohmic contact layer, which are disposed as different multiple layers according to different doping concentrations or component contents. In this embodiment, the material of the epitaxial structure 21 is preferably GaN-based, and the light-emitting layer 212 radiates blue light.

The metal electrode 25 is disposed on the second surface side of the epitaxial structure 21, and electrically connected to the epitaxial structure 21 and the circuit board 1 respectively. The metal electrode 25 may be a single layer, double layers, or a plurality of layers, such as Ti/Al, Ti/Al/Ti/Au, Ti/Al/Ni/Au, V/Al/Pt/Au, and other stacked layers. In an optional embodiment, the light-emitting component further includes a conductive pad 4. The conductive pad 4 directly contacts the circuit board 1 and the metal electrode 25 respectively to achieve electrical connection between the light-emitting element 2 and the circuit board 1.

Traditional high-voltage Micro LED chips that use LED unit conductive bridges for series connection require expansion of chip dimensions. Traditional large-sized LED chips are prone to damage during ICP etching, leading to a problem of reducing the light-emitting efficiency.

To solve the aforementioned problems, please refer to FIG. 2. In this embodiment, viewing from aforementioned the light-emitting element 2 toward the epitaxial structure 21, the first surface has a side edge 24b close to the conductive bridge 3, and an orthogonal projection of the side edge 24b on the circuit board 1 falls within an orthogonal projection of the second surface on the circuit board 1. Through the aforementioned disposing method, a distance between the second surfaces of two light-emitting units connected in series may be made closer compared to a distance between the first surfaces, thereby ensuring that a bridging distance of the conductive bridge 3 on the side of the second surface is effectively reduced. Therefore, the overall size of the chip is reduced, and the light-emitting efficiency is improved. At the same time, a thickness of the conductive bridge 3 may be reduced, the production cost may be lowered, and the stability of the bridging may be ensured, so that there is likely no defects such as cracks or fractures, thereby improving the reliability of the device.

In some preferred embodiments, the epitaxial structure 21 further has sidewalls connected to the first surface and the second surface. Sidewalls extending from the side edge 24b to the second surface are defined as groove sidewalls 24a. The groove sidewall 24a is formed by at least one plane or at least one arc surface or a combination thereof, so that a groove 24 is formed between the groove sidewalls 24a of the light-emitting units connected in series with each other.

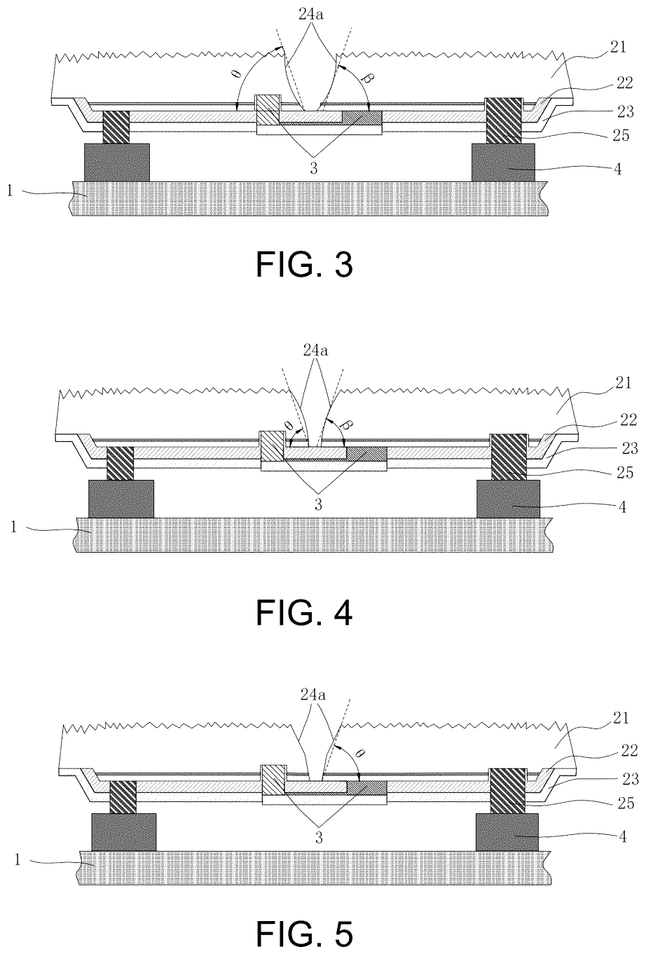

Specifically, as shown in FIG. 1, FIG. 3, and FIG. 4, the groove sidewall 24a may be an inclined plane or an inclined arc surface, that is, a cross-sectional shape thereof is an inverted trapezoid. When the groove sidewall 24a is an inclined arc surface, a range of an angle β between a tangent of the inclined arc surface and the second surface is greater than or equal to 30° and less than 90°, and the angle β may gradually decrease from the direction of the first surface toward the second surface to form a concave arc as shown in FIG. 3, or gradually increase from the direction of the first surface toward the second surface to form a convex arc as shown in FIG. 4. Compared to the concave arc design in FIG. 3, the convex arc design in FIG. 4 may better protect a through hole used for the electrical connection of the conductive bridge 3 from being excessively exposed or even breaking through the epitaxial structure 21 in the process.

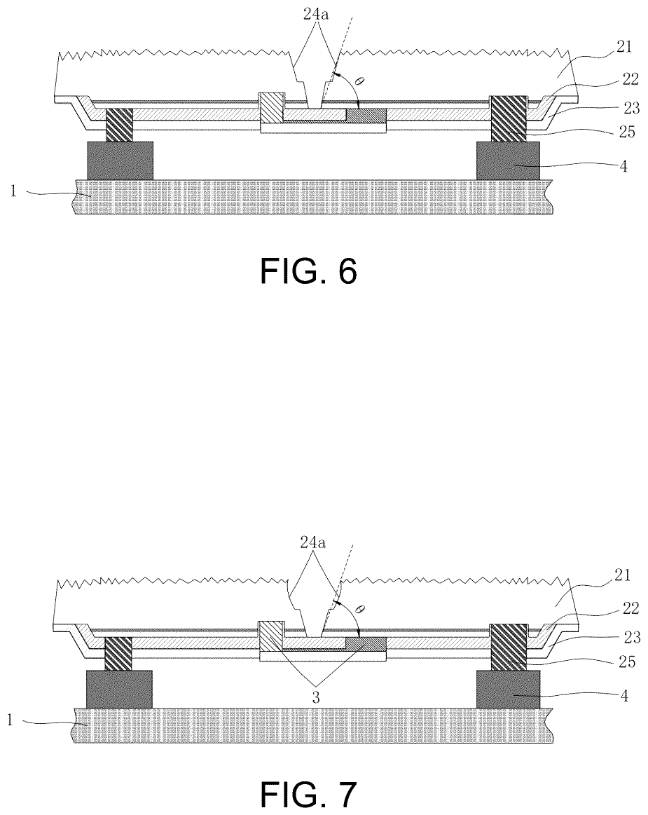

The groove sidewall 24a may further be formed by at least two planes with different inclined angles or at least two arc surfaces with different radii of curvature or a combination thereof. For example, as shown in FIG. 5, the groove sidewall 24a is composed of two planes with different inclined angles. As shown in FIG. 6, the groove sidewall 24a may include a first inclined surface, a horizontal surface, and a second inclined surface extending sequentially from the direction of the first surface toward the second surface to be step-shaped, which may reduce the step difference during creation and is conducive to the stability of the process. To facilitate the processing of the groove sidewall 24a, an inclined angle of the first inclined surface is less than or equal to an inclined angle of the second inclined surface. This inclined angle is an angle between the inclined surface and the second surface.

It should be noted that, the disposing method of the groove sidewall 24a is not limited to what is shown in the drawings. According to the inventive concept, persons skilled in the art may also replace the groove sidewall 24a with other combinations, and the groove sidewall 24a may further be composed of combinations of three or four different planes and arc surface styles, as shown in FIG. 7. The specific arrangements are based on actual requirements, and all such replacements fall within the scope of protection of the disclosure.

In another preferred embodiment, continuously referring to FIG. 1 to FIG. 7, the groove 24 has a bottom edge 24c located at the connection between the groove sidewall 24a and the second surface. An angle θ between the common perpendicular line of the side edge 24b and the bottom edge 24c with the second surface is less than 90°. It should be noted that in the production and manufacturing process, the side edge 24b and the bottom edge 24c are not completely parallel in space due to their own design or manufacturing errors. Therefore, when the side edge 24b and the bottom edge 24c are parallel straight lines, an angle between the plane formed by the side edge 24b and the bottom edge 24c (that is, the plane where the common perpendicular line is located) and the second surface may be defined as θ. When the side edge 24b and the bottom edge 24c are skew lines, the angle between the common perpendicular line between the side edge 24b and the bottom edge 24c with the second surface is defined as θ. Such a limitation of the angle θ being less than 90° may effectively ensure that regardless of how the groove sidewall 24a changes, a bottom area of the groove 24 is smaller than a top area, thereby facilitating the effective deposition of the medium layer 22 and the conductive bridge 3 on the bottom of the groove 24. While the connection stability of the conductive bridge 3 is improved, the conductive bridge 3 is also allowed to be made thinner, thereby reducing the manufacturing cost of the device.

Preferably, a range of the angle θ is greater than or equal to 45° and less than 70°, or greater than or equal to 70° and less than 80°, or greater than or equal to 80° and less than 90°. The aforementioned limitation on the angle θ may effectively avoid the angle θ being too small which would affect the light-emitting area, or too large which would affect the process. Furthermore, the range of the angle θ is greater than 45° and less than 75°, which facilitates the back-plating of the insulation layer 23 of the light-emitting component, thereby effectively protecting the epitaxial structure 21 and the light-emitting layer 212.

In other embodiments, an opening of the groove 24 gradually decreases from the direction of the first surface toward the second surface. Through this arrangement, the groove 24 has a structure that is wider on the top and narrower on the bottom, where a position of the narrow bottom is used for the bridging of the conductive bridge 3 to ensure that the bridging distance of the conductive bridge 3 is effectively reduced, thereby reducing the overall dimension of the chip and improving the light-emitting efficiency. At the same time, the thickness of the conductive bridge 3 may be reduced, the production cost may be lowered, and the stability of the bridging may also be ensured, so that there is likely no defects such as cracks or fractures, thereby improving the reliability of the device.

Optionally, there is a minimum horizontal distance between the groove sidewalls 24a of the light-emitting units connected in series with each other, and the minimum horizontal distance is greater than or equal to 2 microns and less than or equal to 5 microns. The distance range being beneficial for the light-emitting effect of the light-emitting element 2 is adopted, and the stability of the process is ensured. In some other embodiments, there is a maximum horizontal distance between the light-emitting units connected in series, and the maximum horizontal distance is less than the minimum spacing between adjacent light-emitting elements 2.

In addition, in order to protect and insulate the light-emitting element 2, and avoid a foreign object from entering the light-emitting element 2, the light-emitting element 2 further includes an insulation layer 23. The insulation layer 23 covers the second surface, or covers the second surface, and extends to cover part of the sidewall. Specifically, a material of the insulation layer 23 may be a non-conductive material, selected from white inorganic oxides, nitrides, silicon dioxide, silicon nitride, titanium oxide, tantalum oxide, niobium oxide, barium titanate, magnesium fluoride, aluminum oxide, or combinations thereof.

Through holes are formed in the insulation layer 23 to expose the first-type semiconductor layer 211 or the second-type semiconductor layer 213. Specifically, two light-emitting units connected in series may be divided into a first light-emitting unit and a second light-emitting unit, with through holes formed on each of the two light-emitting units connected in series to expose the first-type semiconductor layer 211 and the second-type semiconductor layer 213. The specific circuit connection method between the two is: one end of the conductive bridge 3 is connected to the first-type semiconductor layer 211 of the first light-emitting unit through the through hole, and another end is connected to the second-type semiconductor layer 213 of the second light-emitting unit. At least one metal electrode 25 is connected to the second-type semiconductor layer 213 of the first light-emitting unit, and another at least one metal electrode 25 is connected to the first-type semiconductor layer 211 of the second light-emitting unit. At least one metal electrode 25 and another at least one metal electrode 25 are electrically connected to the circuit board 1, thereby realizing a complete series drive circuit between the first light-emitting unit and the second light-emitting unit.

In a more preferred embodiment, in order to effectively support the entire light-emitting unit and avoid a problem of easy breakage when the conductive bridge 3 needs to bridge across the groove during deposition, a medium layer 22 is also disposed between the light-emitting unit and the insulation layer 23. In this embodiment, the medium layer 22 is configured to support the entire light-emitting unit. An insulating material may be selected. Preferably, a thickness range of the medium layer 22 is 0.5 microns to 1.5 microns, to avoid the medium layer 22 being too thin to provide support, or too thick which wastes the material and increases a process of etching. To improve light-emitting efficiency, the medium layer 22 at least includes a reflective layer, preferably a distributed Bragg reflector (DBR). The medium layer 22 includes alternately stacked first layer and second layer, where a refractive index of the first layer is different from a refractive index of the second layer. The materials of the first layer and the second layer include dielectric oxides including TIO_{X}, SiO_{X}, or AlO_{X}. The reflective layer may further be an omnidirectional reflector (ODR). The reflective layer includes selecting a metal material such as Al, Ag, Au combined with the DBR to form an ODR. Of course, structures such as current spreading layers and transparent conductive layers may also be added to the reflective layer to improve the performance of the entire light-emitting diode.

The medium layer 22 covers a second surface of the light-emitting unit and extends across the groove 24 to cover the second surface of another light-emitting unit connected in series with the light-emitting unit. The conductive bridge 3 is located on a side of the medium layer 22 away from the epitaxial structure 21. Through holes are also formed on the medium layer 22 to facilitate the conductive bridge 3 to connect through the through holes to the first-type semiconductor layer 211 of one light-emitting unit and the second-type semiconductor layer 213 of another light-emitting unit connected in series with each other. At the same time, the insulation layer 23 covers the medium layer 22 and the conductive bridge 3, or covers the medium layer 22 and extends to cover a portion of the sidewall and the conductive bridge 3.

Compared to the aforementioned arrangement of the only insulation layer 23, adding the medium layer 22 enhances the structural support of the entire light-emitting element 2 and improves the stability of the process. At the same time, a contact area between the conductive bridge 3 and the light-emitting element 2 may further be increased, ensuring that the conductive bridge 3 may not have defects such as breakage or cracks in the process, while the coverage of the insulation layer 23 may further protect the conductive bridge 3.

In addition, the aforementioned design places the connection of the through holes and the conductive bridge 3 on the side of the second surface, while the groove 24 is disposed on the side of the first surface, which may effectively avoid the problem in traditional chips where placing all of the elements on the same surface results in poor deposition effect of the conductive bridge 3, easily causing metal deposition discontinuities. At the same time, in the process, the problem of operation deviation and inaccuracy caused by secondary alignment on a removal position of the through hole may also avoided when the removal process of forming the groove 24 is performed.

In another preferred embodiment, viewing from the light-emitting element 2 down to the epitaxial structure 21, a projection of the removal position of the through hole on the epitaxial structure 21 is located outside a projection range of the groove 24 on the epitaxial structure 21. That is, a position where the epitaxial structure 21 is removed to form the through hole is offset from the position of the groove 24, so that in the removal process, removal may be performed on different positions respectively. The design may effectively avoid problems in a traditional removal process where the two are on the same overlapping position, such as poor process stability, increased damage to the device, height differences in the conductive bridge 3, or film deposition discontinuities. Only film deposition on the equal height medium layer 22 is needed, thereby helping to improve a transfer yield of the light-emitting element 2.

Optionally, referring to FIG. 1, a range of a distance H from an electrode of the conductive bridge 3 electrically connected to the first-type semiconductor layer 211 of the light-emitting units connected in series to the bottom of the groove 24 may be disposed to 0.5 microns to 3 microns, to further shorten a bridging distance of the conductive bridge 3, while difficulties in creating the removal area are avoided due to too the short bridging distance, but the embodiment of the disclosure is not limited to thereto.

Referring to FIG. 1 again, the disclosure further provides a light-emitting element 2. The light-emitting element 2 may include at least two adjacent light-emitting units and a conductive bridge 3, and further include a medium layer 22 and an insulation layer 23.

The specific implementation manner of the light-emitting element 2 provided above may refer to the implementation manner of the light-emitting element 2 in the aforementioned light-emitting component, which is not repeated here.

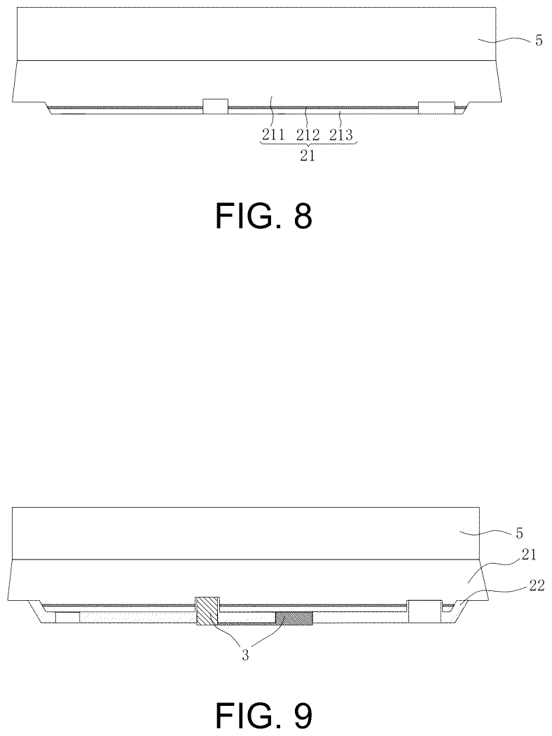

FIG. 8 to FIG. 12 are views of processes of a manufacturing method of a light-emitting component. The manufacturing method of the light-emitting component of the disclosure is described in detail below in conjunction with the schematic views.

Referring to FIG. 8, the epitaxial structure 21 is formed on a growth substrate 5. The epitaxial structure 21 has a first surface and a second surface opposite to each other, and includes a first-type semiconductor layer 211, a light-emitting layer 212, and a second-type semiconductor layer 213 stacked sequentially from the first surface to the second surface. The growth substrate 5 may be an insulation substrate or a conductive substrate. The epitaxial structure 21 may be formed on the growth substrate 5 through physical vapor deposition (PVD), chemical vapor deposition (CVD), and an epitaxial growth method.

Referring to FIG. 9, next, the medium layer 22 is formed on the second surface of the epitaxial structure 21, and the conductive bridge 3 is formed on the medium layer 22. This embodiment applies a back-coated medium layer 22 to the light-emitting element 2, which helps improve the light exit effect. The medium layer 22 may be formed by vacuum evaporation, sputtering, or the CVD. In this embodiment, the medium layer 22 at least includes a reflective layer, preferably the DBR.

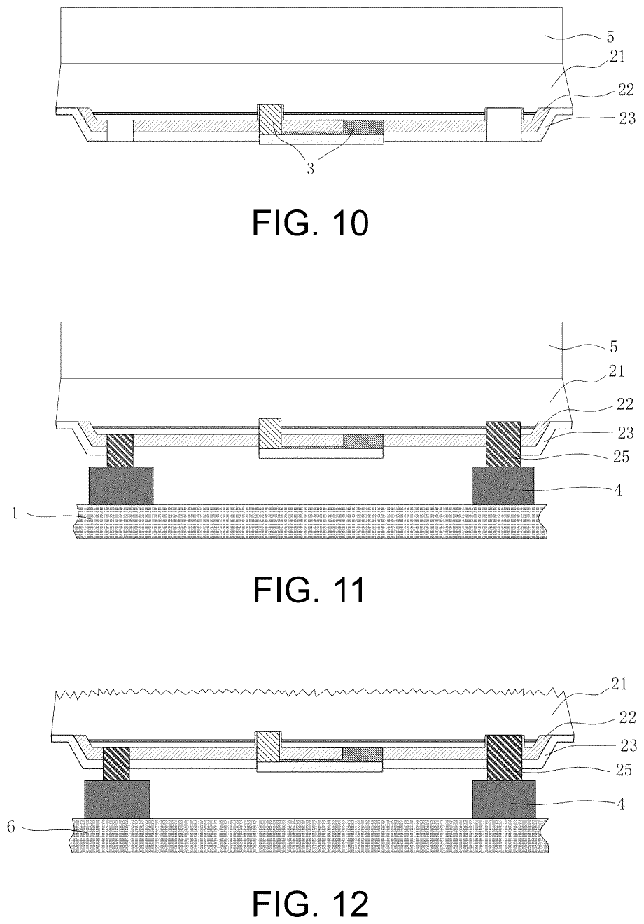

Referring to FIG. 10, the insulation layer 23 is deposited. The insulation layer 23 covers the medium layer 22 and the conductive bridge 3 as well as a portion of the sidewall of the epitaxial structure 21. The insulation layer 23 is preferably made of SiNₓ or SiO₂ materials. Referring to FIG. 11, then several metal electrodes 25 are formed on the insulation layer 23 through the evaporation process. Conductive pads 4 are formed on the metal electrodes 25 and transferred to a temporary substrate 6 (refer to FIG. 12). Next, referring to FIG. 12, the growth substrate 5 is removed to expose the first surface of the epitaxial structure 21. In this embodiment, the first surface may be roughened.

Finally, a portion of the epitaxial structure 21 is removed from the first surface toward the second surface to form a groove 24. The groove 24 divides the epitaxial structure 21 into a series of light-emitting units, and gradually reduces from the first surface toward the second surface, specifically as shown in FIG. 1 to FIG. 7.

In a preferred scheme, the removal process adopts at least one of laser, dry etching, and wet etching. The specific selection may be made according to actual requirements, which is not limited thereto. This embodiment preferably uses a process of ISO etching.

As a preferred scheme, using the light-emitting component described in any of the aforementioned embodiments, or using the light-emitting element described in any of the aforementioned embodiments, or applying the manufacturing method of the light-emitting component described in any of the aforementioned embodiments to a display device, may effectively improve the performance of the display device.

Finally, it should be noted that: the aforementioned embodiments are only configured to illustrate the technical solutions of the disclosure, and are not to limit thereto. Although the disclosure has been described in detail with reference to the foregoing embodiments, persons skilled in the art should understand that they may still modify the technical solutions recorded in the foregoing embodiments, or make equivalent replacements to part or all of the technical features. The modifications or replacements do not make the essence of the corresponding technical solutions deviate from the scope of the technical solutions of the embodiments of the disclosure.

What is claimed is:

1. A light-emitting component, comprising:
a circuit board; and
a plurality of groups of light-emitting elements arranged at intervals on the circuit board, the light-emitting element comprising:
at least two adjacent light-emitting units; and
a conductive bridge, wherein:
the conductive bridge is bridged on the adjacent light-emitting units to electrically connect the adjacent light-emitting units in series;
the light-emitting unit comprises an epitaxial structure and at least one metal electrode;
the epitaxial structure has a first surface and a second surface opposite to each other, and the first surface is a light exit surface;
the conductive bridge is bridged across a side of the second surface;
viewing the epitaxial structure from above the light-emitting element, the first surface has a side edge close to the conductive bridge, and an orthogonal projection of the side edge on the circuit board falls within an orthogonal projection of the second surface on the circuit board; and
the at least one metal electrode is disposed between the epitaxial structure and the circuit board, and is electrically connected to the epitaxial structure and the circuit board.

2. The light-emitting component according to claim 1, wherein the epitaxial structure further has sidewalls connected to the first surface and the second surface, the sidewalls extending from the side edge to the second surface are defined as groove sidewalls, and the groove sidewall is formed by at least one plane or at least one arc surface or a combination thereof, so that a groove is formed between the groove sidewalls of the light-emitting units connected in series with each other.

3. The light-emitting component according to claim 2, wherein the groove sidewall is an inclined plane or an inclined arc surface.

4. The light-emitting component according to claim 3, wherein the groove sidewall is the inclined arc surface, an angle between a tangent of the inclined arc surface and the second surface is β, β is greater than or equal to 30° and less than 90°, and β gradually increases or gradually decreases.

5. The light-emitting component according to claim 2, wherein the groove sidewall is formed by at least two planes with different inclined angles or at least two arc surfaces with different radii of curvature or a combination thereof.

6. The light-emitting component according to claim 2, wherein the groove sidewall includes a first inclined surface, a horizontal surface, and a second inclined surface extending sequentially from a direction of the first surface toward the second surface, and an inclined angle of the first inclined surface is less than or equal to an inclined angle of the second inclined surface.

7. The light-emitting component according to claim 2, wherein the groove has a bottom edge located at a connection between the groove sidewall and the second surface, an angle between a common perpendicular line of the side edge and the bottom edge with the second surface is θ, and θ is less than 90°.

8. The light-emitting component according to claim 7, wherein a range of θ is greater than or equal to 45° and less than 70°, or greater than or equal to 70° and less than 80°, or greater than or equal to 80° and less than 90°.

9. The light-emitting component according to claim 2, wherein the groove gradually decreases from the first surface toward the second surface.

10. The light-emitting component according to claim 2, wherein a minimum horizontal distance between the groove sidewalls of the light-emitting units connected in series with each other is greater than or equal to 0.1 micron and less than or equal to 2 microns.

11. The light-emitting component according to claim 1, wherein a maximum horizontal distance between the light-emitting units connected in series is less than a minimum spacing between the adjacent light-emitting elements.

12. The light-emitting component according to claim 1, wherein in the light-emitting element composed of two light-emitting units connected in series, a length of the light-emitting element does not exceed 200 microns, and a width of the light-emitting element does not exceed 100 microns.

13. The light-emitting component according to claim 1, wherein a thickness range of the conductive bridge is 0.5 microns to 1.5 microns, and a material of the conductive bridge comprises at least one of a dielectric medium material, a metal material, and a semiconductor material.

14. The light-emitting component according to claim 2, wherein the light-emitting element further comprises:
a medium layer covering a second surface of the light-emitting unit and extending across the groove to cover the second surface of another light-emitting unit connected in series with the light-emitting unit; and
an insulation layer covering the medium layer and the conductive bridge, or covering the medium layer and extending to cover a portion of the sidewall and the conductive bridge.

15. The light-emitting component according to claim 14, wherein a thickness range of the medium layer is 0.5 microns to 1.5 microns, and the medium layer at least comprises a reflection layer.

16. The light-emitting component according to claim 14, wherein the epitaxial structure comprises a first type semiconductor layer, a light-emitting layer, and a second type semiconductor layer stacked sequentially from the first surface toward the second surface; and
at least one through hole exposing the first type semiconductor layer or the second type semiconductor layer is disposed on the medium layer and the insulation layer, the conductive bridge covers the medium layer, and is electrically connected to the first type semiconductor layer and the second type semiconductor layer of two light-emitting units connected in series with each other through the through hole.

17. The light-emitting component according to claim 16, wherein a range of a distance from an electrode of the conductive bridge electrically connected to the first type semiconductor layer of the light-emitting units connected in series with each other to a bottom of the groove is 0.5 microns to 3 microns.

18. A light-emitting element, comprising:
at least two adjacent light-emitting units; and
a conductive bridge, wherein:
the conductive bridge is bridged on the adjacent light-emitting units to electrically connect the adjacent light-emitting units in series;
the light-emitting unit comprises an epitaxial structure and at least one metal electrode;
the epitaxial structure has a first surface and a second surface opposite to each other, and the first surface is a light exit surface;
the conductive bridge is bridged across a side of the second surface; and
viewing the epitaxial structure from above the light-emitting element, the first surface has a side edge close to the conductive bridge, and an orthogonal projection of the side edge on the epitaxial structure falls within an orthogonal projection of the second surface on the epitaxial structure.

19. The light-emitting element according to claim 18, wherein the epitaxial structure further has sidewalls connected to the first surface and the second surface, the sidewalls extending from the side edge to the second surface are defined as groove sidewalls, and the groove sidewall is formed by at least one plane or at least one arc surface or a combination thereof, so that a groove is formed between the groove sidewalls of the light-emitting units connected in series with each other.

20. The light-emitting element according to claim 19, wherein the light-emitting element further comprises:
a medium layer covering the second surface of the light-emitting unit and extending across the groove to cover the second surface of another light-emitting unit connected in series with the light-emitting unit; and
an insulation layer covering the medium layer and the conductive bridge, or covering the medium layer and extending to cover a portion of the sidewall and the conductive bridge.
